(19) United States
(12) Patent Application Publication
(10) Pub. No.: US 2021/0263720 A1
(43) Pub. Date: Aug. 26, 2021

(54) SYSTEMS AND METHODS FOR FLASH MEMORY CONFLICT AVOIDANCE

(71) Applicant: QUALCOMM Incorporated, San Diego, CA (US)

(72) Inventors: Madhu Yashwanth Boenapalli, Hyderabad (IN); Sai Praneeth Sreeram, Anantapur (IN); Surendra Paravada, Hyderabad (IN); Venu Madhav Mokkapati, Hyderabad (IN)

(21) Appl. No.: 16/798,887

(22) Filed: Feb. 24, 2020

(51) Int. Cl. G06F 8/65; G06F 11/07; G06F 11/10; G06F 3/06; G11C 11/4076

(52) U.S. Cl. CPC G06F 8/65; G06F 11/0757; G06F 11/106; G11C 11/4076; G06F 3/0652; G06F 3/0653; G06F 3/0679; G06F 3/0619

(57) ABSTRACT

Systems and methods for flash memory conflict avoidance cause a firmware over the air (FOTA) update to be given priority over a scrubbing operation unless the memory element meets or exceeds a predefined health degradation parameter. When the memory element meets or exceeds the predefined health degradation parameter, the scrubbing operation is given priority over the FOTA update. By enforcing these priorities, scrubbing and FOTA updates do not occur at the same time and conflicts are thereby avoided. Since conflicts are avoided, the chance of memory corruption is decreased and the chance of “bricking” the computing device is likewise decreased.

### BACKGROUND

### I. Field of the Disclosure

The technology of the disclosure relates generally to memory and more particularly, to FLASH memory and still more particularly, to conflict avoidance in Not-AND (NAND) FLASH memory.

### II. Background

Computers and computing devices have become common in modern society. The proliferation of computing devices is attributable in part to their increasing power provided in ever smaller packages. As the size of computing devices has shrunk, it has become practical to have mobile computing devices. Both mobile computing devices and traditional desktop style computing devices rely on memory elements to store applications, data, operating systems, and the like.

One popular type of memory for mobile computing devices is FLASH memory, which may be made from electronically erasable program read only memory (EEPROM) which in turn may be formed from Not-AND (NAND) gate structures. Such NAND-based FLASH memory is sometimes referred to as NAND FLASH. NAND FLASH degrades as a function of time and use and various techniques have been developed to extend FLASH lifetimes. One such technique is known as scrubbing, by which information in one partition of the memory element is written to a new partition and individual memory cells are evaluated for age and reliability. After verifying the reliability of the memory cells in the first partition, those memory cells may be reused (e.g., by the original information or by new information). Unreliable memory cells are no longer used. In a typical computing device, NAND FLASH may be scrubbed about once every three months.

NAND FLASH may also store firmware, which may periodically be updated to provide new functionality, fix bugs, or in response to some other demand. For mobile computing devices, a process termed firmware over the air (FOTA) has been developed which allows information to be downloaded to the mobile computing device wirelessly (i.e., over the air) and then written into the memory cells where the older version of the firmware resides. It should be appreciated that there may be occasions when scrubbing takes place concurrently with a FOTA update. This concurrent use of the memory cells may create conflicts and may cause the information to become corrupted to the extent that the computing device is non-operational. Accordingly, a technique for conflict avoidance may be of benefit to avoid “bricking” the computing device.

### SUMMARY OF THE DISCLOSURE

Aspects disclosed in the detailed description include systems and methods for flash memory conflict avoidance. In an exemplary aspect, a firmware over the air (FOTA) update is given priority over a scrubbing operation unless the memory element meets or exceeds a predefined health degradation parameter. When the memory element meets or exceeds the predefined health degradation parameter, the scrubbing operation is given priority over the FOTA update. By enforcing these priorities, scrubbing and FOTA updates do not occur at the same time and conflicts are thereby avoided. Since conflicts are avoided, the chance of memory corruption is decreased and the chance of “bricking” the computing device is likewise decreased.

In this regard, in one aspect, a method for managing conflicts in memory use is disclosed. The method includes receiving a FOTA update request for a memory partition. The method also includes suspending a scrubbing operation for the memory partition for a predetermined amount of time while completing the FOTA update request. The method also includes resuming the scrubbing operation when the FOTA update request is completed.

In another aspect, an integrated circuit (IC) is disclosed. The IC includes an interface configured to be coupled to a memory circuit comprising a plurality of memory partitions over a bus. The IC also includes a control circuit coupled to the interface. The control circuit is configured to receive a FOTA update request for a memory partition in the memory circuit. The control circuit is also configured to suspend a scrubbing operation for the memory partition for a predetermined amount of time while completing the FOTA update request. The control circuit is also configured to resume the scrubbing operation when the FOTA update request is completed.

In another aspect, a computing device is disclosed. The computing device includes a bus. The computing device also includes a memory circuit comprising a plurality of memory partitions. The memory circuit is coupled to the bus. The computing device also includes a control circuit coupled to the bus. The control circuit is configured to receive a FOTA update request for a memory partition in the memory circuit. The control circuit is also configured to suspend a scrubbing operation for the memory partition for a predetermined amount of time while completing the FOTA update request. The control circuit is also configured to resume the scrubbing operation when the FOTA update request is completed.

### BRIEF DESCRIPTION OF THE FIGURES

FIG. 1 is a diagram of an exemplary environment in which firmware over the air (FOTA) updates may occur;

FIG. 2 is a block diagram of a computing device having a memory element which may be subjected to FOTA updates and scrubbing operations;

FIG. 3 is an automobile which may have a computing device having memory elements that may benefit from exemplary aspects of the present disclosure;

FIG. 4 is block diagram of a FLASH memory element having memory partitions having information therein that may be scrubbed or updated;

FIGS. 5A-5C illustrate a FLASH memory undergoing a scrub operation and what may happen if a concurrent FOTA update occurs;

FIG. 6 is a flowchart illustrating an exemplary process for conflict avoidance between FOTA updates and scrubbing operations;

FIG. 7 is a timing diagram illustrating how a FOTA update may request suspension of a scrubbing operation;

FIG. 8 is a second timing diagram illustrating a telescoping suspension of a scrubbing operation by a FOTA update;

FIG. 9 is a second flowchart illustrating an exemplary process for conflict avoidance between FOTA updates and scrubbing operations; and

FIG. 10 is a third flowchart illustrating an exemplary process for conflict avoidance between FOTA updates and scrubbing operations.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include systems and methods for flash memory conflict avoidance. In an exemplary aspect, a firmware over the air (FOTA) update is given priority over a scrubbing operation unless the memory element meets or exceeds a predefined health degradation parameter. When the memory element meets or exceeds the predefined health degradation parameter, the scrubbing operation is given priority over the FOTA update. By enforcing these priorities, scrubbing and FOTA updates do not occur at the same time and conflicts are thereby avoided. Since conflicts are avoided, the chance of memory corruption is decreased and the chance of “bricking” the computing device is likewise decreased.

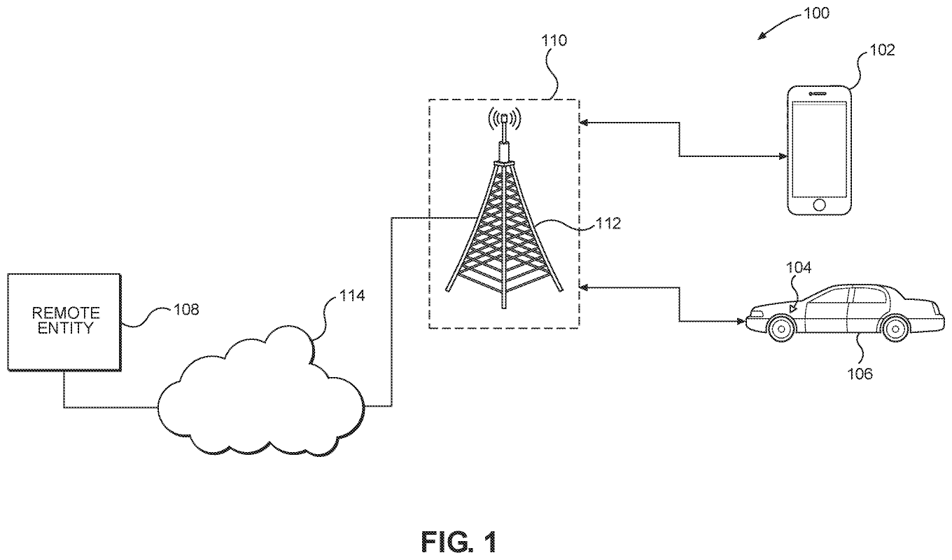

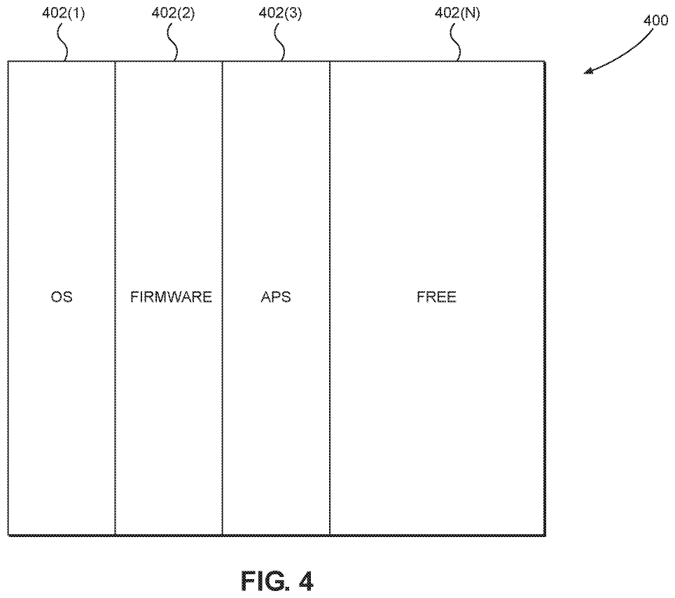

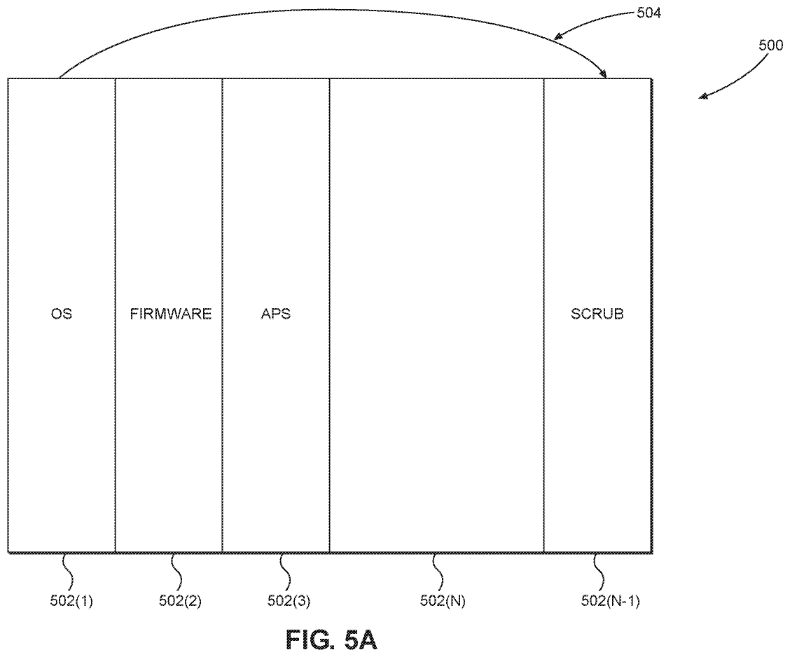

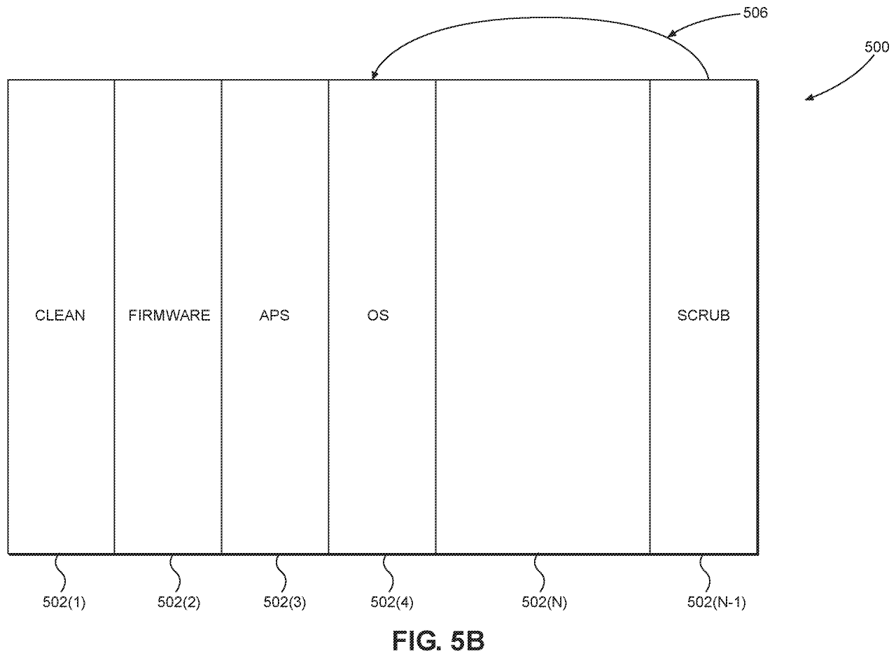

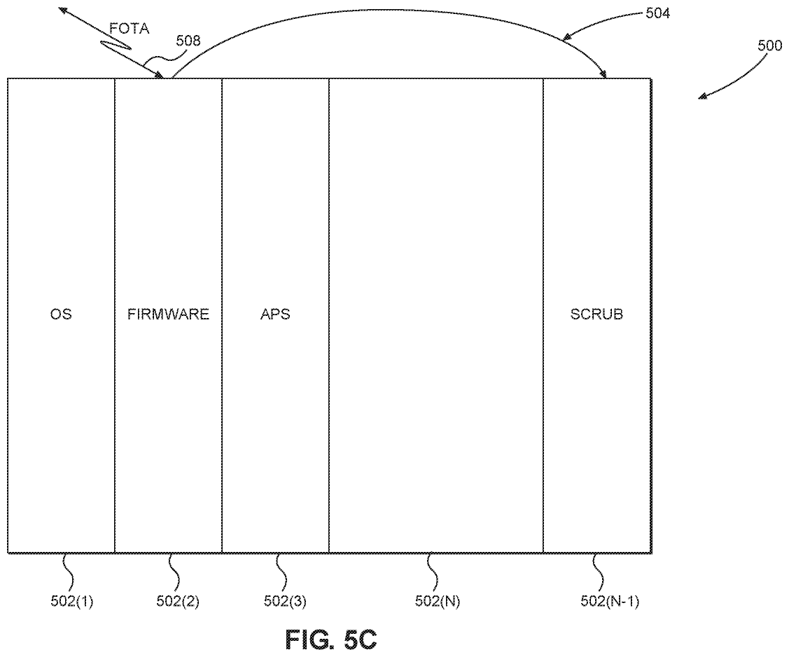

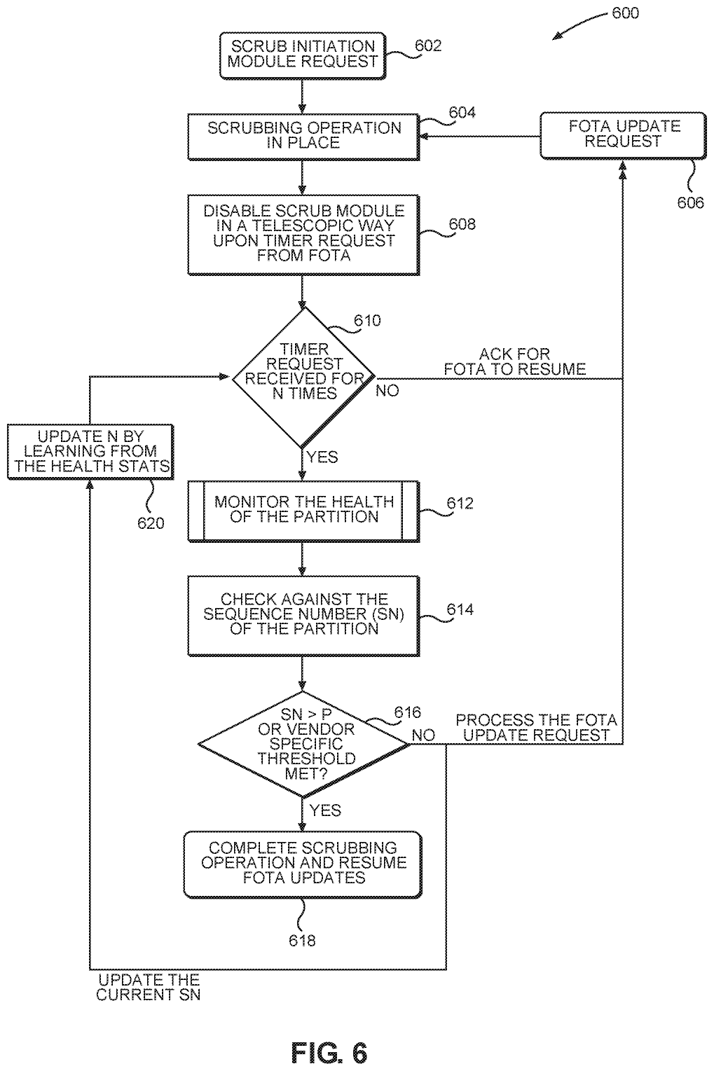

Before addressing particulars of prioritizing the scrubbing operation or the FOTA updates, a brief overview of exemplary contexts that may benefit from the present disclosure is provided with reference to FIGS. 1-3. An overview of a memory circuit is provided in FIG. 4 while FIGS. 5A-5C show how the scrubbing operation may conflict with the FOTA update in the absence of the present disclosure. A discussion of specific exemplary aspects of the present disclosure begins below with reference to FIG. 6.

In this regard, FIG. 1 illustrates an environment 100 with computing devices therein. Specifically, a mobile computing device 102 and a computing device 104 within a vehicle 106 are illustrated. The mobile computing device 102 and the computing device 104 may communicate with a remote entity 108 (e.g., a software company, a firmware server, or the like that provides firmware updates) through a wireless network 110, which may include a base station 112 that is connected to the remote entity 108 through a network 114, which may include the Internet, the public land mobile network (PLMN), the public switched telephone system (PSTN), or the like. The remote entity 108 may provide FOTA updates to the mobile computing device 102 or the computing device 104 through the network 114 and the wireless network 110 through any conventional cellular or wireless protocol as is well understood. While illustrated as a cellular type wireless network 110, it should be appreciated that it may also be possible to have a small cell, BLUETOOTH Low Energy (BLE), General Packet Radio Service (GPRS), or WIFI type wireless network 110 and the precise details of the wireless network 110 are not central to the present disclosure.

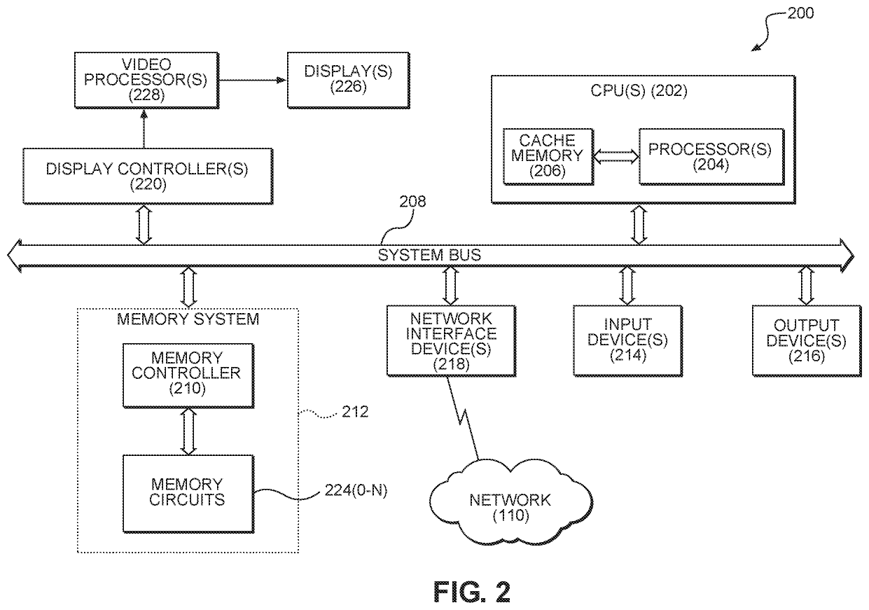

FIG. 2 illustrates an example of a processor-based system 200 that may be the mobile computing device 102 or the computing device 104 of FIG. 1. In this example, the processor-based system 200 includes one or more central processing units (CPUs) 202, each including one or more processors 204. The CPU(s) 202 may be an application processor or a mobile device modem (MDM) or the like. The CPU(s) 202 may have cache memory 206 coupled to the processor(s) 204 for rapid access to temporarily stored data. The cache memory may be a Not-AND (NAND) FLASH erasable electronic programmable read only memory (EEPROM) or the like. The CPU(s) 202 is coupled to a system bus 208 and can intercouple devices included in the processor-based system 200. As is well known, the CPU(s) 202 communicates with these other devices by exchanging address, control, and data information over the system bus 208. For example, the CPU(s) 202 can communicate bus transaction requests to a memory controller 210 as an example of a slave device. Although not illustrated in FIG. 2, multiple system buses 208 could be provided.

Other devices can be connected to the system bus 208. As illustrated in FIG. 2, these devices can include a memory system 212, one or more input devices 214, one or more output devices 216, one or more network interface devices 218, and one or more display controllers 220, as examples. The input device(s) 214 can include any type of input device, including, but not limited to, input keys, switches, voice processors, etc. The output device(s) 216 can include any type of output device, including, but not limited to, audio, video, other visual indicators, etc. The network interface device(s) 218 can be any devices configured to allow exchange of data to and from the network 110. As noted, the network 110 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 218 can be configured to support any type of communications protocol desired and in particular may accept FOTA updates for firmware within the processor-based system 200. The memory system 212 can include one or more memory circuits 224(0-N). The memory circuits 224(0-N) may also be NAND FLASH EEPROM or the like.

The CPU(s) 202 may also be configured to access the display controller(s) 220 over the system bus 208 to control information sent to one or more displays 226. The display controller(s) 220 sends information to the display(s) 226 to be displayed via one or more video processors 228, which process the information to be displayed into a format suitable for the display(s) 226. The display(s) 226 can include any type of display, including, but not limited to, a cathode ray tube (CRT), a liquid crystal display (LCD), a plasma display, a light emitting diode (LED) display, etc.

While FIG. 2 illustrates an exemplary computer architecture for the computing devices 102, 104, it should be appreciated that other architectures may also benefit from the present disclosure, and the present disclosure is not limited to a specific computing device or mobile computing device.

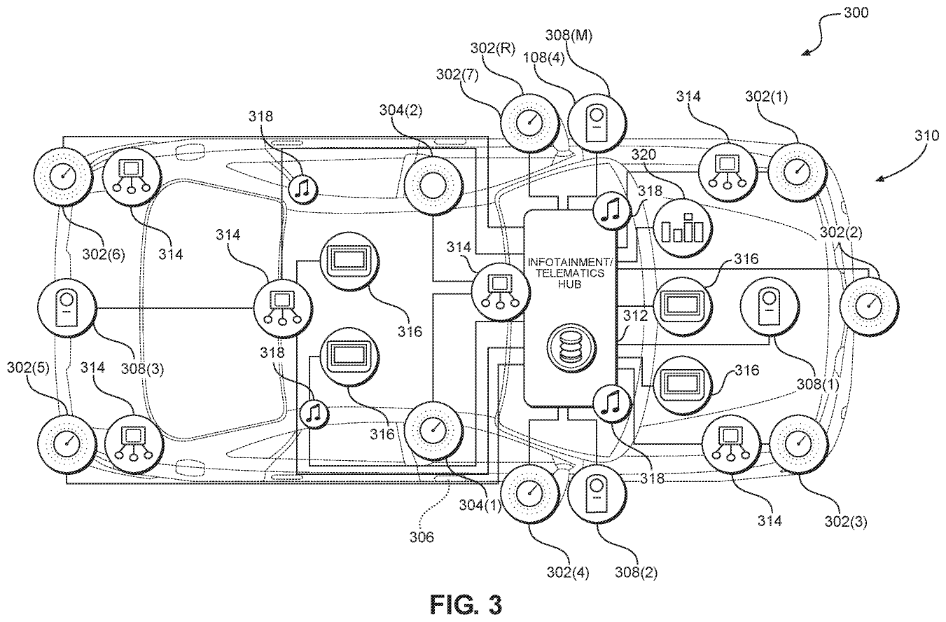

FIG. 3 illustrates a vehicle 300, analogous to the vehicle 106 of FIG. 1 with an internal computing device analogous to the computing device 104 therein. The vehicle 300 is illustrated as an automobile, but could be another form of vehicle such as a motorcycle, a boat, a plane, or the like. The vehicle 300 may include a variety of sensors 302(1)-302(R), where, as illustrated R=7. It should be appreciated that more or fewer than seven sensors 302 may be present. The sensors 302(1)-302(R) may be proximity sensors that use sonar, lasers, or some form of radar to detect proximate objects. Additionally, the vehicle 300 may include one or more internal sensors 304(1)-304(2). The internal sensors 304(1)-304(2) may detect whether a door 306 is open or some other internal condition of the vehicle 300 (e.g., driver has fallen asleep). The vehicle 300 may further include one or more cameras 308(1)-308(M), where as illustrated, M=4. It should be appreciated that fewer or more than four cameras 308 may be present. The vehicle 300 may have an internal network 310 that couples some or all of the sensors 302 and 304 to a hub 312. Network bridges 314 may be present to assist in providing the network 310. Displays 316 and speakers 318 may be present and coupled to the network 310. The hub 312 may include a control system or control circuit that accesses software stored in memory 320, which may be NAND FLASH memory. Likewise, individual sensors 302 or 304 may include associated NAND FLASH memory with firmware therein. The network 310 may be a single homogeneous network such as a common bus having a multi-drop or ring topology, or may be formed from distinct communication links such as separate point-to-point cables. The vehicle 300 of FIG. 3 is provided by way of example of a context for memory circuits and is not intended to be limiting. Likewise, other vehicle architectures may also benefit from the present disclosure.

FIG. 4 illustrates an exemplary memory circuit 400 which may be used in either the mobile computing device 102, the computing device 104, or the processor-based system 200. The memory circuit 400 may be a NAND FLASH based EEPROM memory circuit and may include one or more memory partitions 402(1)-402(N) (sometimes just called partitions), where a first partition 402(1) may contain the information for an operating system (OS), the second partition 402(2) may contain the information for firmware, the third partition 402(3) may contain information for applications (APS), and the nth partition 402(N) may be free memory ready to be used as needed. Other, not illustrated partitions may include code partitions, secondary boot loader (SBL) partitions, and a multi-image boot information block (MIBIB) partition. It should be appreciated that NAND FLASH has certain limitations in that blocks could become bad at runtime and, after a fixed number of reads, a page may deteriorate and lose data. The loss of data may not be complete because, as the NAND FLASH deteriorates, there may be unwanted bit-flips which merely corrupt some of the data. In most installations, the NAND FLASH is expected to survive fifteen (15) years of use. Scrubbing is generally used to help extend lifetime of the NAND FLASH, identify bad blocks, and relocate data to good blocks within the NAND FLASH.

In general, scrubbing involves the relocation of a partition and an update to the MIBIB. Thus, while FOTA updates have been discussed above, a brief discussion of scrubbing operations and problems that can arise from FOTA/scrubbing conflicts is provided with reference to FIGS. 5A-5C. In particular, FIG. 5A shows a memory circuit 500 with memory partitions 502(1)-502(N) (also sometimes just called partitions) similar to the memory circuit 400. However, the memory circuit 500 includes a scrub partition 502(N−1). During a scrubbing operation, an existing partition (e.g., first partition 502(1)) is copied into the scrub partition 502(N−1) (generally illustrated by arrow 504) and the first partition 502(1) is then “cleaned” by erasing the original contents and/or deleting pointers/address tables pointing to the first partition 502(1) and rewriting the information from the scrub partition 502(N−1) to a new partition such as fourth partition 502(4) (see FIG. 5B) (generally shown by arrow 506). The first partition 502(1) may have each individual memory cell evaluated for age, use, or other factor to determine if the memory cell is still “healthy” and reliable. Such NAND FLASH evaluations are well known in the art.

Conflicts may occur when there is a FOTA update at the same time the firmware partition is being scrubbed as illustrated in FIG. 5C. That is, the FOTA update 508 may be writing (i.e., changing bits) information into the second partition 502(2) as the scrubbing operation is trying to copy the second partition 502(2) into the scrub partition 502(N−1). The resulting information in the scrub partition 502(N−1) may include information that is corrupted because some of the information is pre-FOTA update and some information is post-FOTA update, with the amalgamation being inoperable or otherwise inoperative.

To avoid such conflicts, exemplary aspects of the present disclosure contemplate allowing FOTA updates to have priority over and suspend scrubbing operations unless the health of the memory to be scrubbed is below a predefined threshold. When the health of the memory to be scrubbed is below the predefined threshold, FOTA updates are suspended until the scrubbing operation is complete.

In this regard, FIG. 6 illustrates a flowchart of a process 600 for implementing exemplary aspects of the conflict avoidance of the present disclosure. The process 600 may be managed by a control circuit in the CPU (e.g., the processor 204 in the CPU 202) or a control circuit in a modem of a mobile computing device The process 600 begins with a scrub initiation module request (block 602). That is, a timer may expire and the operating system invokes the scrub initiation module to begin a scrubbing operation. While the scrubbing operation is in place (block 604), a FOTA update request is received (block 606). On receipt of the FOTA update request, the scrubbing operation is disabled or suspended for a predetermined amount of time in a telescopic way upon timer request from the FOTA update request (block 608). The control circuit may determine if a timer request has been received for N times (block 610). N may be configurable based on a frequency of FOTA updates. If the answer to block 610 is no, then the control circuit sends an acknowledge (ACK) signal for the FOTA request to resume. If the answer to block 610 is yes, then the control circuit monitors the health of a given partition (block 612). In particular, the control circuit may check against the sequence number (SN) of the partition (block 614) and if the sequence number is greater than a predefined threshold (P) (block 616), then the scrubbing operation may be completed and then FOTA updates resumed (block 618). P may be vendor configurable based on the total FLASH life cycle and the periodicity of the scrub requests. If however, the sequence number is less than the predefined threshold P, then the FOTA update request may be processed and there is an update to N by learning from the health statistics (block 620).

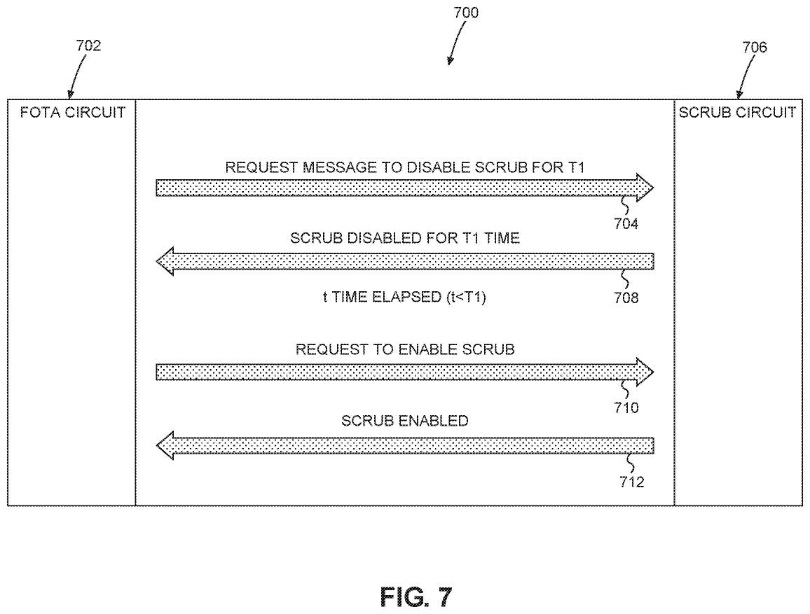

By way of further explanation, the control circuit in the modem or CPU 202 may include a FOTA module (not shown). The FOTA module may be software or hardware and may handle the FOTA updates. Further, exemplary aspects of the present disclosure allow the FOTA module in the control circuit to disable scrubbing for a requested amount of time (e.g., T1). The disable request may disable scrubbing until an enable scrub request is sent or for the requested amount of time. An example message flow 700 showing these requests is provided with reference to FIG. 7, where a FOTA circuit 702 sends a disable scrub request 704 for time T1 to a scrub circuit 706. The scrub circuit 706 may send an ACK signal 708. At some time less than T1, when the FOTA update is finished, the FOTA circuit 702 may then request enablement of the scrubbing operation through a request signal 710, and the scrub circuit 706 may signal 712 that the scrub is enabled. Alternatively, not illustrated, if a timer corresponding to T1 expires, the scrub circuit 706 may signal that the scrubbing operation is being enabled.

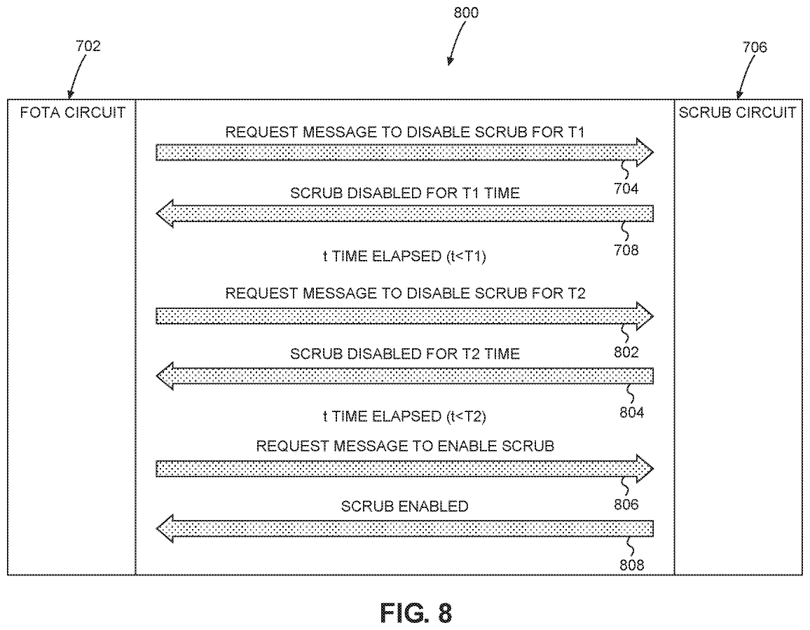

Note that it is possible that the FOTA circuit 702 may not complete the FOTA update in the time T1, and thus, exemplary aspects of the present disclosure contemplate that the FOTA circuit 702 may make time extension requests (sometimes referred to as timer requests) as better illustrated by a message flow 800 illustrated in FIG. 8. Message flow 800 begins like message flow 700 with the FOTA circuit 702 sending a disable scrub request 704 for time T1 (i.e., a timer request) to a timer circuit (not shown) the scrub circuit 706. The scrub circuit 706 may send an ACK signal 708. At some time less than T1, when the FOTA circuit 702 recognizes that the FOTA update will not finish before T1, the FOTA circuit 702 may send a second disable request 802 to disable the scrubbing operation for an additional time T2 (a second or plurality of timer requests). This second disable request may use the same timer circuit or a different timer circuit. The scrub circuit 706 may send a second ACK signal 804. At some time less than T2, when the FOTA update is finished, the FOTA circuit 702 may then request enablement of the scrubbing operation through a request signal 806, and the scrub circuit 706 may signal 808 that the scrub is enabled. Alternatively, not illustrated, if a timer corresponding to T2 expires, the scrub circuit 706 may signal that the scrubbing operation is being enabled. It should be appreciated that while only one extension is shown, the FOTA circuit 702 may request multiple extensions (e.g., in a telescoping fashion).

To prevent a telescoping FOTA update from monopolizing use of the FLASH memory and completely precluding a scrubbing operation, there may be a mechanism in place to preclude the FOTA update from proceeding if the health of the NAND FLASH is below a certain threshold. As shown in the process 600, that threshold may be defined in terms of a sequence number. That is, the FOTA circuit should take responsibility in taking feedback from the NAND FLASH memory regarding the health of cells which may be degraded due to the read-disturb phenomenon and/or other adverse environmental conditions (e.g., heat) using health descriptors. Such health may limit the number of times that the FOTA update can delay a scrubbing operation. Once past this limit, a health monitor scrubbing operation may be triggered.

One way that the health monitor may be implemented is through the previously mentioned sequence number. Each partition may be assigned a sequence number that is incremented for every erase or scrubbing operation performed on that partition. By way of example, if an expected lifecycle of a FLASH memory circuit is fifteen years, and scrubbing operations occur every two months, then a maximum sequence number may be ninety (15 years×6 scrubs/year). Accordingly, a health monitor check infers that the health of a given partition is low if the sequence number is greater than forty-five (45), and forty-five may be set as the threshold above which a FOTA update is held in abeyance while scrubbing takes place and below which the FOTA update delays the scrubbing operation. This threshold may be set by a memory vendor at some other level as needed or desired (e.g., if the vendor knows the life expectancy is different or the scrub frequency is different). Once a scrubbing operation is complete and the partitions are rearranged, the scrub circuit may hand over control of the partitions to the FOTA circuit along with the changed page-table. Then, the FOTA circuit may resume its process.

In an exemplary aspect, the FOTA circuit may capture certain additional information in evaluating the health of the memory circuit. In particular, the device temperature may be determined from a temperature sensor (not shown) and the sequence number may be used. The scrub disable timer may be a function of both the temperature and the sequence number. That is, the timer may be allowed to be high if the temperature is low and the sequence number is below a threshold (e.g., P defined above). However, if either the temperature is high or the sequence number is above the threshold (P), then the timer may be limited to a low number or the FOTA update may be suspended until the scrub is done. Still other parameters may be evaluated in determining when to suspend or defer FOTA updates in favor of the scrubbing operation.

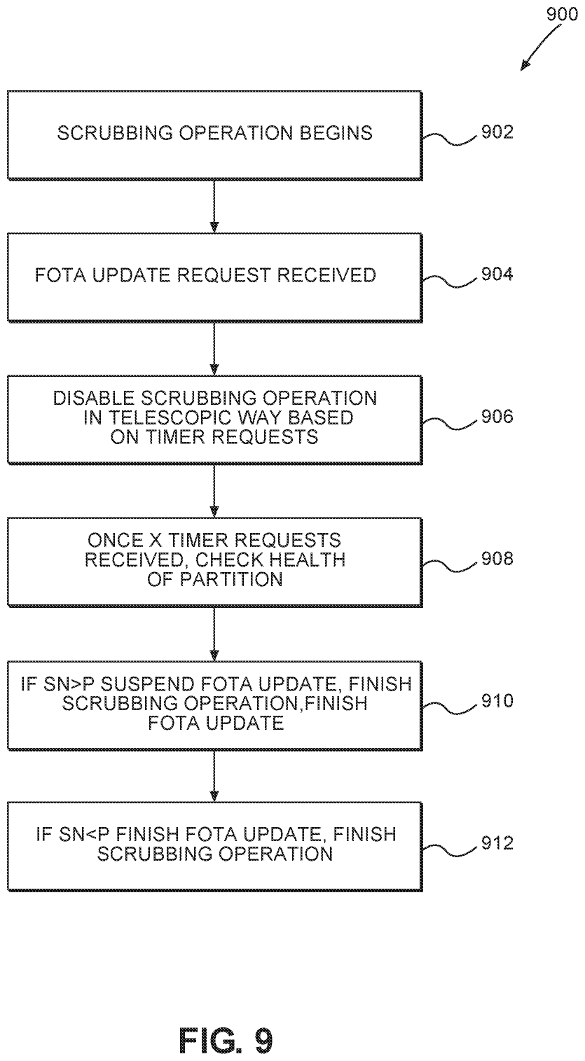

An alternate process 900 is provided in FIG. 9. In process 900 the process starts with a scrub operation active or the beginning of a scrubbing operation (block 902). While the scrubbing operation is active, a FOTA update request is received (block 904). The control circuit may disable the scrubbing operation in a telescopic way based on timer requests from the FOTA circuit (block 906). Once a predefined number (X) of timer requests have been received, the control circuit may check the health of the partition as indicated by SN and/or temperature (block 908). If SN>P then the control circuit may suspend the FOTA update and finish the scrubbing operation, then resume the FOTA update (block 910). If the SN<P, then the control circuit allows the FOTA update to complete and then finishes the scrubbing operation (block 912).

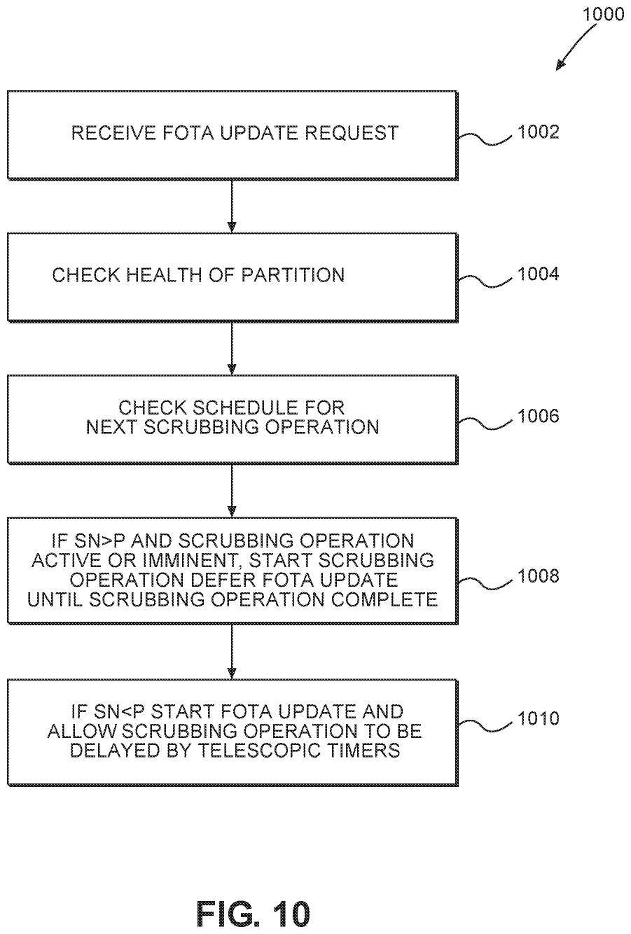

Still another alternate process 1000 is illustrated in FIG. 10. The process 1000 begins when a FOTA update request is received (block 1002). The control circuit checks the health of the partition (block 1004) (e.g., by checking sequence number, temperature, or other health degradation parameter). The control circuit may further check the schedule for the next scrubbing operation (block 1006). If SN>P and a scrubbing operation is active or imminent (less than a predefined time remains before next scrub), then the control circuit may start the scrubbing operation, defer the FOTA update until the scrubbing operation is complete, then perform the FOTA update (block 1008). Alternatively, if SN<P, then the FOTA update is performed and allowed to delay the scrubbing operation by telescoping timers as described above (block 1010).

The systems and methods for flash memory conflict avoidance according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

What is claimed is:

1. A method for managing conflicts in memory use, the method comprising:
receiving a firmware over the air (FOTA) update request for a memory partition;
suspending a scrubbing operation for the memory partition for a predetermined amount of time while completing the FOTA update request; and
resuming the scrubbing operation when the FOTA update request is completed.

2. The method of claim 1, wherein receiving the FOTA update request comprises receiving the FOTA update request while a scrubbing operation for memory containing the memory partition is active.

3. The method of claim 1, wherein suspending the scrubbing operation comprises receiving a first timer request in which the FOTA update request is to be completed.

4. The method of claim 3, further comprising receiving a second timer request extending the first timer request in which the FOTA update request is to be completed.

5. The method of claim 3, further comprising receiving a plurality of subsequent timer requests extending the first timer request in which the FOTA update request is to be completed.

6. The method of claim 5, further comprising comparing the plurality of subsequent timer requests to a threshold number of requests.

7. The method of claim 6, further comprising suspending a FOTA update associated with the FOTA update request if the plurality of subsequent timer requests exceeds the threshold number of requests.

8. The method of claim 7, further comprising completing the scrubbing operation while the FOTA update is suspended, then resuming the FOTA update.

9. The method of claim 1, further comprising assigning a health degradation parameter to the memory partition.

10. The method of claim 9, wherein the health parameter comprises a sequence number reflecting a number of erase or scrub operations performed on the memory partition.

11. The method of claim 9, wherein the health parameter comprises a temperature reading.

12. An integrated circuit (IC) comprising:
an interface configured to be coupled to a memory circuit comprising a plurality of memory partitions over a bus; and
a control circuit coupled to the interface, the control circuit configured to:
receive a firmware over the air (FOTA) update request for a memory partition in the memory circuit;
suspend a scrubbing operation for the memory partition for a predetermined amount of time while completing the FOTA update request; and
resume the scrubbing operation when the FOTA update request is completed.

13. The IC of claim 12 wherein the IC comprises an application processor.

14. The IC of claim 12, wherein the IC comprises a mobile device modem.

15. The IC of claim 12, wherein the control circuit is further configured to initiate the scrubbing operation prior to receiving the FOTA update request.

16. The IC of claim 12, further comprising a timer circuit configured to receive a timer request associated with the FOTA update request.

17. The IC of claim 12, wherein the control circuit is further configured to assign a health parameter to the memory partition.

18. The IC of claim 17, wherein the health parameter comprises a sequence number reflecting a number of erase or scrub operations performed on the memory partition.

19. The IC of claim 17, wherein the health parameter comprises a temperature reading.

20. The IC of claim 12 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

21. A computing device comprising:
a bus;
a memory circuit comprising a plurality of memory partitions, the memory circuit coupled to the bus; and
a control circuit coupled to the bus and configured to:
receive a firmware over the air (FOTA) update request for a memory partition in the memory circuit;
suspend a scrubbing operation for the memory partition for a predetermined amount of time while completing the FOTA update request; and
resume the scrubbing operation when the FOTA update request is completed.
